(19) United States
(12) Patent Application Publication
(10) Pub. No.: US 2026/0156978 A1
(43) Pub. Date: Jun. 4, 2026

(54) LIGHT-EMITTING DIODE COMPRISING AN ALN-BASED EMISSIVE REGION CONTAINING GALLIUM ATOMS AND/OR INDIUM ATOMS

(71) Applicants: COMMISSARIAT A L'ENERGIE ATOMIQUE ET AUX ENERGIES ALTERNATIVES, Paris (FR); UNIVERSITÉ GRENOBLE ALPES, Saint-Martin-D'heres (FR)

(72) Inventors: Rémy VERMEERSCH, Grenoble Cedex 09 (FR); Bruno DAUDIN, Grenoble Cedex 09 (FR)

(73) Assignees: COMMISSARIAT A L'ENERGIE ATOMIQUE ET AUX ENERGIES ALTERNATIVES, Paris (FR); UNIVERSITÉ GRENOBLE ALPES, Saint-Martin-D'heres (FR)

(21) Appl. No.: 18/876,213

(22) PCT Filed: Jun. 14, 2023
(86) PCT No.: PCT/FR2023/050868

§ 371 Date: Dec. 18, 2024

(30) Foreign Application Priority Data
Jun. 20, 2022 (FR) 2206040

(51) Int. Cl. H10H 20/825; H10H 20/01; H10H 20/815; H10H 20/821

(52) U.S. Cl. CPC H10H 20/8252; H10H 20/01335; H10H 20/815; H10H 20/821

(57) ABSTRACT

A light-emitting diode that includes a substrate, a portion of a first type, of Al_{X1}Ga_{(1-X1-Y1)}In_{Y1}N doped according to a first type of conductivity, where X1>0 and X1+Y1≤1, arranged above the substrate, an emissive portion comprising a dilute AlN alloy containing gallium atoms and/or indium atoms with a concentration of less than 30%, a portion of a second type, of Al_{X2}Ga_{(1-X2-Y2)}In_{Y2}N doped according to a second type of conductivity, opposite to the first type of conductivity, where X2>0 and X2+Y2≤1. The emissive portion is arranged between the portion of the first type and the portion of the second type.

### TECHNICAL FIELD

The invention relates to the field of broadband semiconductor-based Light-Emitting Diodes (LEDs). Advantageously, the invention applies to making LEDs emitting light in the ultraviolet (UV) range, especially in the wavelength range between about 230 nm and 310 nm, especially for fields related to disinfection, preservation and/or agriculture.

### STATE OF PRIOR ART

In particular, the bactericidal effect, and more generally the disinfecting effect, of UV radiation derives from the absorption band of DNA of micro-organisms (bacteria, microbes, viruses) in a wavelength range from about 230 nm to 310 nm. The damage to DNA of micro-organisms through the absorption of UV radiation hinders their reproduction and results in killing them. Maximum disinfectant effect is achieved with radiation that has a spectral distribution as close as possible to this absorption band of DNA of the micro-organisms to be destroyed.

Disinfection by exposure to UV radiation is currently done using different devices such as KrCl lamps or mercury vapour lamps. However, these devices have drawbacks.

KrCl lamps are excimer lamps whose emission spectrum is narrow relative to the absorption spectrum of DNA of the micro-organisms to be destroyed and which therefore do not provide an optimal disinfecting effect. In addition, these lamps generate ozone, which limits them to niche applications.

Mercury vapour lamps, on the other hand, are fragile and have a limited lifespan. Furthermore, their fine emission lines do not cover the entire absorption spectrum of DNA of the micro-organisms to be destroyed. Finally, these lamps contain mercury, the use of which is banned in the long term because of its high toxicity.

Semiconductor materials of the III element nitride family, especially including GaN, AlN, IN or alloys thereof, especially ternary and quaternary alloys, are particularly adapted to making LEDs emitting in the UV range. Such LEDs are made, for example, in the form of a stack of layers or nanowires, or even with a hybrid structure as described in document FR 3 109 470 Al. In these LEDs, varying the aluminium content in the composition of the semiconductor of the quantum multi-wells makes it possible to control emission wavelength of the LEDs. It is therefore possible, with these LEDs, to span the entire range of wavelengths desired to have an optimum disinfectant effect by varying the level of aluminium in the semiconductor composition of the quantum multi-wells. However, the fineness of the emission peaks generally obtained with such LEDs makes it difficult to cover the entire desired wavelength range with a single LED. It is therefore generally necessary to resort to several LEDs with emission peaks at different wavelengths, especially to cover the entire UV range.

### DISCLOSURE OF THE INVENTION

One purpose of the present invention is to provide a light-emitting diode with the broadest possible emission spectrum in the UV range.

To achieve this purpose, the invention provides a light-emitting diode including at least:
a substrate;
a portion, said to be of a first type, of Al_{X1}Ga_{(1-X1-Y1)}In_{Y1}N doped according to a first type of conductivity, with X1>0 and X1+Y1≤1, arranged above the substrate;
an emissive portion comprising a dilute AlN alloy containing gallium and/or indium atoms with a concentration of less than 30 %;
a portion, said to be of a second type, of Al_{X2}Ga_{(1-X2-Y2)}In_{Y2}N doped according to a second type of conductivity, opposite to the first type of conductivity, with X2>0 and X2+Y2 ≤1, the emissive portion being arranged between the portion of the first type and the portion of the second type.

The LED according to the invention thus includes an emissive portion formed of a dilute AlN alloy containing gallium and/or indium atoms, i.e. not homogeneous on the nanometric scale in terms of distribution of Al and/or Ga and/or In atoms. The potential experienced by the charge carriers circulating and recombining in the emissive portion is locally lowered by the presence of these Ga and/or In atoms randomly incorporated into the dilute alloy, thus inducing a broader-band light emission than LEDs of prior art.

Unlike LEDs of prior art that emit in the UV range by virtue of potential wells formed between n-and p-doped layers, it is suggested making an LED whose emissive part is formed by a portion of AlN containing gallium and/or indium atoms in small amounts so as to form a dilute alloy. Unlike a quantum well forming a potential well having defined emission energy, the emissive portion of the LED according to the invention is characterised by an emissive zone where charge carriers are subjected to a potential having local fluctuations created by the presence of these Ga and/or In atoms and forming emitting zones extending over a range that can be especially from 230 to 310 nm.

Furthermore, in the LED according to the invention, the emissive portion can be arranged directly against the n-and p-doped semiconductor portions of the LED (corresponding to the portions of the first type and of the second type), unlike the emissive portion of a quantum well which is arranged against barrier layers.

In the dilute alloy of the emissive portion, the AlN of the emissive portion may comprise gallium and/or indium atoms in random substitution for aluminium atoms, or may comprise gallium and/or indium atoms in substitution for aluminium atoms sufficiently close together to form locally a region having the characteristics of an AlGaN or AllnN or AIGalnN alloy, or may comprise gallium and/or indium atoms bonded to nitrogen atoms and capable of locally forming nanocrystals, or nanocrystallites or aggregates, of AlGaN or AllnN or AlGalnN.

The fact that the use, to form the emissive portion of the LED, of a dilute AlN alloy containing gallium and/or indium atoms with a concentration of less than 30% leads to light emission in a broad spectrum of the UV range is surprising and not obvious. Indeed, in a homogeneous alloy of AlN comprising GaN molar fraction of 1%, the gap obtained is 203 nm or 6.1 eV, and for a GaN molar fraction of 10%, the gap is 2225 nm or 5.5 eV. A person skilled in the art desiring to make an AlGaN-based LED emitting at a wavelength of 280 nm or 4.43 eV would naturally be led to devise a homogeneous ternary alloy which should contain a GaN molar fraction of between 60 and 62%, and not to use a dilute alloy as suggested here.

With such an emissive portion, the LED according to the invention can emit in a much wider wavelength range than the emission spectrum of a quantum well LED, for example in the wavelength range from about 200 nm to about 350 nm and advantageously in the wavelength range from about 230 nm to about 310 nm. Such an LED is therefore particularly effective when used for disinfecting applications.

Furthermore, with respect to a device using several LEDs to cover the entire desired spectral range, the fact of being able to cover this entire range with a single LED makes it possible to have similar or higher efficiency while consuming less power.

Another advantage is that making such an LED does not require forming multiple quantum wells, and is therefore simpler to make and dispenses with difficulties inherent in controlling the composition of the semiconductors used to form such wells.

The LED provided is especially adapted for disinfection applications (bacterial, microbial, viral), especially for water and/or air. Such an LED can also be used, for example, for skin disinfection applications when its radiation corresponds to light with a wavelength in the order of 230 nm, the penetration depth of which is limited to the stratum corneum epidermis.

The LED provided is in particular applicable to general use domestic applications, such as disinfecting a refrigerator, in a car, purifying water leaving a distribution point such as a fountain or tap, etc.

The LED may further include an intermediate portion of GaN doped according to first type of conductivity arranged between the substrate and the portion of the first type. The presence of such an intermediate portion facilitates growth of the portion of the first type, especially when the LED is made in the form of nanowires.

The proportion of gallium and/or indium atoms in the material of the emissive portion can advantageously be less than or equal to 10%, or between about 1% and 10%, or less than or equal to 5%, or even between 1% and 5%. Such a proportion of gallium and/or indium atoms in the material of the emissive portion enables the LED to emit in the wavelength range particularly well adapted to disinfection applications.

The light-emitting diode may further include a buffer layer arranged between the substrate and the portion of the first type, or between the substrate and the intermediate portion when the diode includes such an intermediate portion.

The material of the buffer layer may be based on GaN or AlN or AlGaN.

The first type of conductivity may correspond to n-type, and the second type of conductivity may correspond to p-type. However, the reverse is also possible.

Advantageously:
n-type dopants present in the material of one of the portions of either the first type or the second type may correspond to silicon and/or sulphur and/or germanium atoms;
p-type dopants present in the material of the other of the portions of either the first type or the second type may correspond to magnesium and/or beryllium atoms.

The material of the other of the portions of the first type and of the second type may include indium atoms, which makes it possible to increase the amount of p-type dopants, especially magnesium atoms, incorporated in the material of this other portion, thus facilitating the doping thereof.

The material of the portion of the first type and/or of the portion of the second type may include AlN. This configuration prevents the portions of the first type and of the second type from having a barrier effect with respect to the emissive portion, which is AlN-based.

In a first embodiment, the LED may include a plurality of nanowires extending from the substrate, each of the nanowires including at least the portions of the first type and of the second type and the emissive portion.

In a second embodiment, at least the portions of the first type and of the second type and the emissive portion may form a stack of layers arranged on the substrate.

The invention also provides a method for making a light-emitting diode, including at least:
making, on a substrate, a portion, said to be of a first type, of Al_{X1}Ga_{(1-X1-Y1)}In_{Y1}N doped according to a first type of conductivity, with X1>0 and X1+Y1≤1;
making, on the portion of the first type, an emissive portion comprising a dilute AlN alloy containing gallium and/or indium atoms with a concentration of less than 30%, and advantageously less than 10% or even less than 5%;
making, on the emissive portion, a portion, said to be of a second type of Al_{X2}Ga_{(1-X2-Y2)}In_{Y2}N doped according to a second type of conductivity, opposite to the first type of conductivity, with X2 >0 and X2+Y2≤1.

Throughout the document, the term “on” is used without distinction as to the orientation in space of the element to which the term is concerned. For example, in the characteristic “an element formed on a substrate”, the face of the substrate on which the element is formed is not necessarily oriented upwardly but may correspond to a face oriented along any direction. Furthermore, the arrangement of a first element on a second element must be understood as possibly corresponding to the arrangement of the first element against the second element, without any intermediate element between the first and second elements, or as possibly corresponding to the arrangement of the first element on the second element with one or more intermediate elements arranged between the first and second elements.

### BRIEF DESCRIPTION OF THE DRAWINGS

The present invention will be better understood upon reading the description of exemplary embodiments given by way of indicating and in no way limiting purposes, with reference to the appended drawings in which:

FIG. 1 represents an LED comprising an emissive portion based on an AlN containing gallium and/or indium atoms and forming a dilute alloy, being one object of the present invention, according to a first embodiment;

FIG. 2 represents an emission spectrum of the LED according to the first embodiment;

FIG. 3 represents an LED comprising an emissive portion based on AlN containing gallium and/or indium atoms and forming a dilute alloy, being one object of the present invention, according to a second embodiment.

Identical, similar or equivalent parts of the different figures described hereinafter bear the same numerical references so as to facilitate switching from one figure to another.

The different parts represented in the figures are not necessarily drawn to a uniform scale, to make the figures more legible.

The different possibilities (alternatives and embodiments) should be understood as not being mutually exclusive and may be combined with one another.

### DETAILED DESCRIPTION OF PARTICULAR EMBODIMENTS

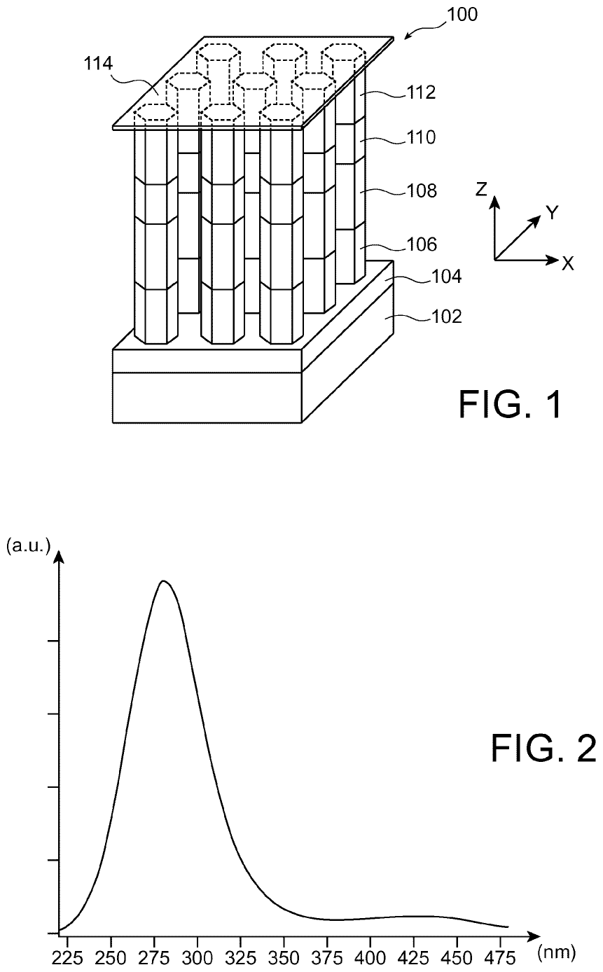

FIG. 1 described below represents an LED 100 according to a first embodiment of the invention.

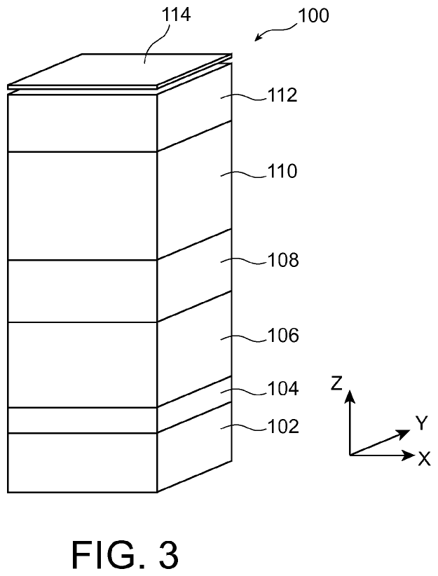

In the description below, the term ‘thickness’ is used to designate the dimension parallel to the axis Z represented in FIGS. 1 and 3, i.e. the dimension parallel to the direction along which the nanowires of the LED 100 extend in the first embodiment, or the stack direction of the different layers of the LED 100 in the second embodiment.

The LED 100 includes a substrate 102 on which the other elements of the LED 100 are arranged and which serves as a mechanical support for these other elements. In this first embodiment, the substrate 102 includes sapphire, for example. Other types of substrate may be used, comprising for example a semiconductor material such as silicon. The thickness of the substrate 102 is, for example, several hundred microns.

In these figures, the LED 100 also includes a buffer layer 104 arranged on the substrate 102. Advantageously, the buffer layer 104 includes AlN or AlGaN or GaN. The thickness of the buffer layer 104 is, for example, between about 0.5 um and 3 um. It may optionally be electrically doped and contain other chemical elements, especially Indium or Boron. This buffer layer promotes growth of the portion 106.

The LED 100 includes, on the buffer layer 104, a plurality of nanowires substantially extending in the direction of the thickness of the LED 100, i.e. along a direction substantially perpendicular to the surface of the substrate 102 on which the buffer layer 104 is formed. In FIG. 1, all the nanowires are represented as being perpendicular to the surface of the buffer layer 104 on which the nanowires are made. In practice, these nanowires may not all be perfectly perpendicular to this surface of the buffer layer 104, and the angles formed between the growth surface of these nanowires and the growth directions of these nanowires may vary by several degrees, or even by ten degrees or more. By way of example, the diameter of each nanowire and the distance between the growth axes of two adjacent nanowires, i.e. their periodicity, may be between about 100 nm and 300 nm. Furthermore, the LED 100 can include a number of nanowires of between about 1 million (for a surface area of 100×100 um²) and 10 million (for a surface area of 300×300 um²), with a mean density for example equal to about 100 wires/um² on the substrate 102.

In the exemplary embodiment of FIG. 1, each nanowire includes an intermediate portion 106 of GaN doped according to a first type of conductivity (n type in the exemplary embodiment of FIG. 1). By way of example, the thickness of the intermediate portion 106 is between about 100 nm and 1 micron.

Alternatively, it is possible that the nanowires of the LED 100 do not include these intermediate portions 106.

In each nanowire, the intermediate portion 106 has thereabove a portion 108, said to be of a first type, of Al_{X1}Ga_{(1-X1-Y1)}In_{Y1}N doped according to the first type of conductivity, with X1>0 and X1+Y1≤1. According to one advantageous embodiment, the material of this portion 108 includes sulphur and/or silicon and/or germanium atoms and/or corresponds to AlN. By way of example, the thickness of the portion 108 is between about 100 nm and 1 um.

According to one exemplary embodiment, the n-type doping of the semiconductors of the portions 106, 108 is obtained by incorporating silicon atoms into the semiconductors of the portions 106, 108, for example implemented upon depositing the semiconductor serving to make these portions. The concentration of dopants in the semiconductors of the portions 106, 108 is, for example, between about 10¹⁶ at/cm³ and 10²¹ at/cm³.

The portion 108 of each nanowire has thereabove an emissive portion 110, or active portion, of AlN containing gallium and/or indium atoms. The proportion, or concentration, of Ga and/or In atoms in AlN of the emissive portion 110 is less than 30% and, for example, between about 1% and 10% or even between 1% and 5%. By way of example, the thickness of the emissive portion 110 is between about 25 nm and 100 nm.

In each nanowire, the emissive portion 110 has thereabove a portion 112, said to be of a second type, of Al_{X2}Ga_{(1-X2-Y2)}In_{Y2}N doped according to a second type of conductivity (p type in the exemplary embodiment of FIG. 1), opposite to the first type of conductivity, with X2>0 and X2+Y2≤1. According to one advantageous embodiment, the material of this portion 112 includes beryllium and/or magnesium atoms and/or corresponds to AlN. By way of example, the thickness of the portion 112 is between about 10 nm and 100 nm, and advantageously between about 10 nm and 50 nm. The material of the portion 112 may include indium atoms, which makes it possible to increase the amount of p-dopants, especially magnesium atoms, incorporated in the material of this portion 112, thus facilitating the doping thereof.

According to one exemplary embodiment, the p-type doping of the semiconductor of the portion 112 is achieved by incorporating magnesium atoms into the semiconductor of the portion 112, for example upon depositing this semiconductor. The concentration of dopants in the semiconductor of the portion 112 is, for example, between about 10¹⁶ at/cm³ and 10²¹ at/cm³.

Lastly, the portion 112 of each nanowire has thereabove an ohmic contact layer 114 arranged on the tops of the nanowires and forming an electrical contact for one of the electrodes of the LED 100. This ohmic contact layer 114 includes at least one electrically conductive material that is transparent to the wavelengths to be emitted by the LED 100, such as for example ITO or advantageously diamond, or a highly electrically doped semiconductor.

FIG. 2 represents the emission spectrum of a set of nanowires of the LED 100 described above, when the emissive portion 110 includes AlN containing gallium atoms. In this spectrum, the amplitude is expressed in arbitrary units. This spectrum clearly illustrates light emission obtained in the wavelength range from about 230 nm to 340 nm, especially covering the absorption range of DNA of the micro-organisms to be killed when this LED 100 is used to destroy these micro-organisms.

An exemplary embodiment of the method for making the LED 100 is described below.

The buffer layer 104 is first made on the substrate 102, for example by implementing a MOCVD (Metal Organic Chemical Vapour Deposition) type deposition.

A growth mask is then made on the buffer layer 104 in order to make the nanowires. This mask includes, for example, circular openings made, for example, by lithography in a layer of material adapted to make this mask. The diameter and periodicity of these openings can be, for example, between about 100 nm and 300 nm.

The intermediate portions 106 are then made by growth or deposition through the openings in the mask, onto the buffer layer 104.

Doping of the portions 106 is then made, for example by incorporating silicon atoms into the semiconductor formed by growth.

Portions 108 of the first type are then made on the portions 106 by growth or deposition through the openings of the mask.

Doping of the portions 108 is then made, for example by incorporating silicon and/or sulphur and/or germanium atoms.

The emissive portions 110 are then made on the portions 108, for example by growth or deposition. Gallium and/or indium atoms are incorporated therein in order to form the dilute alloy of these portions 110.

Portions 112 of the second type are then made on the emissive portions 110, for example by growth or deposition.

Doping of the portions 112 is then made, for example by incorporating magnesium and/or beryllium atoms.

The ohmic contact layer 114 is then made on the tops of the nanowires, for example by deposition.

The growth or deposition steps described above correspond, for example, to Molecular Beam Epitaxy (MBE) or MOCVD type deposition. The doping operations can be implemented in situ in this growth or deposition equipment.

FIG. 3 described below represents the LED 100 according to a second embodiment.

As compared to the LED 100 according to the first embodiment previously described, the LED 100 according to this second embodiment is not formed by a set of nanowires made on the buffer layer 104, but by a stack of layers of materials made on the buffer layer 104, the length and width (dimensions along the axes X and Y in FIG. 3) of each of these layers corresponding to the length and width of the LED 100. The materials of these layers 106, 108, 110 and 112 in FIG. 3, as well as the thicknesses of these layers, are thus similar to those of the portions 106, 108, 110 and 112 of materials of each of the nanowires of the LED 100 according to the first embodiment.

As an alternative to the first and second embodiments described above, it is possible for the LED 100 not to include the buffer layer 104, the nanowires or layers in this case being directly made on the substrate 102.

1. A light-emitting diode, comprising:
a substrate
a portion of a first type, of Al_{X1}Ga_{(1-X1-Y1)}In_{Y1}N doped according to a first type of conductivity, with X1>0 and X1+Y1≤1, arranged above the substrate;
an emissive portion comprising a dilute AlN alloy comprising gallium and/or indium atoms with a concentration of less than 30 %; and
a portion of a second type, of Al_{X2}Ga_{(1-X2-Y2)}In_{Y2}Ndoped according to a second type of conductivity, opposite to the first type of conductivity, with X2>0 and X2+Y2≤1, wherein the emissive portion is arranged between the portion of the first type and the portion of the second type.

2. The light-emitting diode according to claim 1, further comprising:
an intermediate portion of GaN doped according to the first type of conductivity arranged between the substrate and the portion of the first type.

3. The light-emitting diode according to claim 1, wherein a proportion of gallium and/or indium atoms in the emissive portion is less than or equal to 10%.

4. The light-emitting diode according to claim 1, further comprising:
a buffer layer arranged between the substrate and the portion of the first type.

5. The light-emitting diode according to claim 4, wherein the material of the buffer layer is based on GaN or AlN or AlGaN.

6. The light-emitting diode according to claim 1, wherein:
n-type dopants present in the material of one of the portions of either the first type or the second type correspond to silicon and/or sulphur and/or germanium atoms, and
p-type dopants present in the material of the other of said portions of either the first type or the second type correspond to magnesium and/or beryllium atoms.

7. The light-emitting diode according to claim 1, wherein the material of the portion of the first type and/or of the portion of the second type comprises AlN.

8. The light-emitting diode according to claim 1, further comprising:
a plurality of nanowires extending from the substrate each of the nanowires comprising the portions of the first type and of the second type and the emissive portion.

9. The light-emitting diode according to claim 1, wherein the portions of the first type and of the second type and the emissive portion form a stack of layers arranged on the substrate.

10. A method for making a light-emitting diode, the method comprising:
making, on a substrate a portion of a first type, of Al_{X1}Ga_{(1-X1-Y1)}In_{Y1}N doped according to a first type of conductivity, with X1>0 and X1+Y1≤1;
making, on the portion of the first type, an emissive portion comprising a dilute AlN alloy comprising gallium and/or indium atoms with a concentration of less than 30%; and
making, on the emissive portion a portion of a second type, of Al_{X2}Ga_{(1-X2-Y2)}In_{Y2}N doped according to a second type of conductivity, opposite to the first type of conductivity, with X2>0 and X2+Y2≤1.

11. The light-emitting diode according to claim 2, further comprising:
a buffer layer arranged between the substrate and the intermediate portion.

12. The light-emitting diode according to claim 11, wherein the material of the buffer layer is based on GaN or AlN or AlGaN.
